(19) United States
(12) Patent Application Publication
(10) Pub. No.: US 2012/0171501 A1
(43) Pub. Date: Jul. 5, 2012

(54) PROCESS FOR SURFACE TREATING MAGNESIUM ALLOY AND ARTICLE MADE WITH SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); DUN MAO, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/188,561

(22) Filed: Jul. 22, 2011

(30) Foreign Application Priority Data
Dec. 30, 2010 (CN) 201010614873.3

(51) Int. Cl. B32B 15/04; C23C 14/06; C23C 14/34

(52) U.S. Cl. 428/469; 204/192.15

(57) ABSTRACT

A process for treating the surface of magnesium alloy comprises providing a substrate made of magnesium alloy. Then an inorganic chemical conversion film is formed on the substrate by an inorganic chemical conversion treatment. An organic chemical conversion film is subsequently formed on the inorganic chemical conversion film by an organic chemical conversion treatment. Then a ceramic coating comprising refractory metal compound is formed on the chemical conversion film by physical vapor deposition. An article made of magnesium alloy created by the present process also is provided.

### CROSS-REFERENCE TO RELATED APPLICATIONS

This application is related to co-pending U.S. patent applications (Attorney Docket No. US35144, US36044, and US36046, each entitled “PROCESS FOR SURFACE TREATING MAGNESIUM ALLOY AND ARTICLE MADE WITH SAME”, each invented by Chang et al. These applications have the same assignee as the present application. The above-identified applications are incorporated herein by reference.

### BACKGROUND

1. Technical Field

The disclosure generally relates to a process for surface treating magnesium alloy, and articles made of magnesium alloy treated by the process.

2. Description of Related Art

Magnesium alloys are widely used in manufacturing components (such as housings) of electronic devices and cars because of their properties such as light weight and quick heat dissipation. However, magnesium alloys have a relatively low erosion resistance and abrasion resistance. One method for enhancing the erosion resistance of magnesium alloy is to form ceramic coatings on its surface. However, cast magnesium alloy often has many pinholes on its surface. The ceramic coatings over these pinholes are usually thinner and weaker than other portions having no pinholes, rendering pitting corrosion more likely at these locations.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary process for the surface treating of magnesium alloy and articles made of magnesium alloy treated by the process. Moreover, in the drawings, like reference numerals designate corresponding parts throughout the several views. Wherever possible, the same reference numbers are used throughout the drawings to refer to the same or like elements of an embodiment.

FIG. 1 is a cross-sectional view of an exemplary article treated in accordance with the present process.

FIG. 2 is a block diagram of a process for the surface treating of magnesium alloy according to an exemplary embodiment.

FIG. 3 is a schematic view of a vacuum sputtering machine for processing the exemplary article shown in FIG. 1.

### DETAILED DESCRIPTION

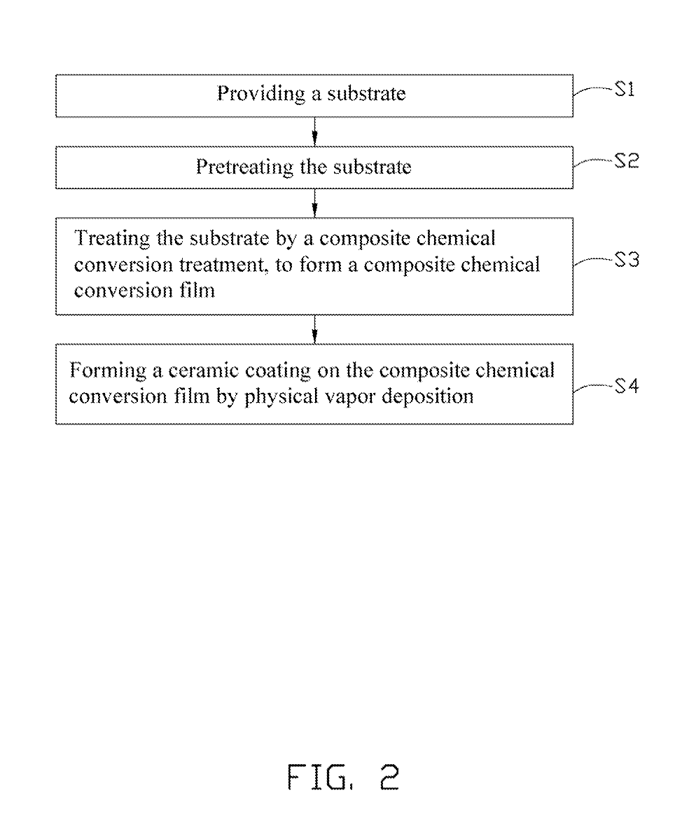

Referring to FIG. 2, an exemplary process for the surface treatment of magnesium alloy may include steps S1 to S4.

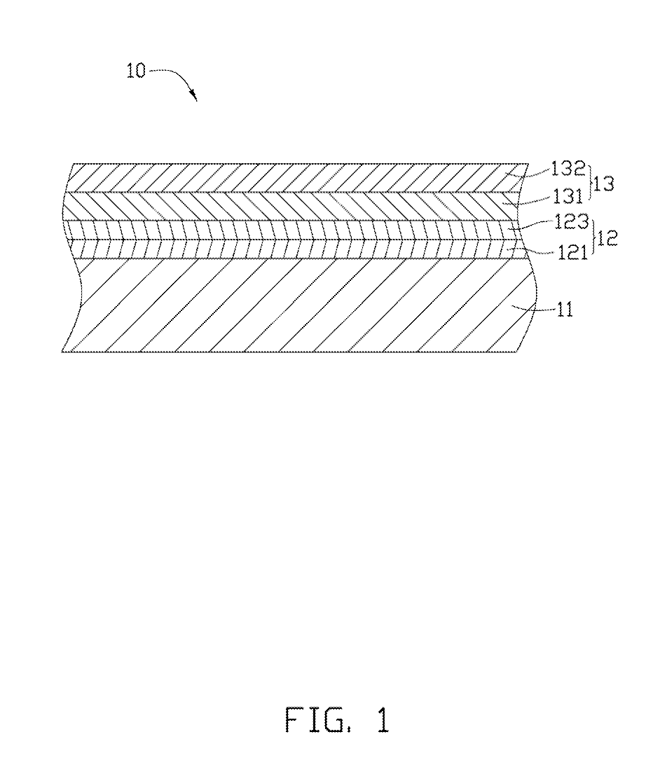

In step S1, referring to FIG. 1, a substrate 11 is provided. The substrate 11 is made of a magnesium alloy, such as Mg—Al alloy, or Mg—Al—Zn alloy.

In step S2, the substrate 11 is pretreated. The pretreatment may include the following steps.

Firstly, the substrate 11 is chemically degreased with an aqueous solution, to remove impurities such as grease or dirt from the substrate 11. The aqueous solution may contain about 25 g/L-30 g/L sodium carbonate (Na₂CO₃), about 20 g/L-25 g/L trisodium phosphate dodecahydrate (Na₃PO₄.12H₂O), and an emulsifier. The emulsifier may be a trade name emulsifier OP-10 (a condensation product of alkylphenol and ethylene oxide) at a concentration of about 1 g/L-3 g/L. The substrate 11 is immersed in the aqueous solution at a temperature of about 60° C.-80° C. for about 30 s-60 s. Then, the substrate 11 is rinsed for about 20 s-60 s.

Then, the substrate 11 is activated using an activating solution, to improve the bonding ability of the surface of the substrate 11 with the subsequent film. The activating solution may be an aqueous solution containing hydrofluoric acid (HF) at a concentration of about 1%-3% by weight. The substrate 11 is immersed in the activating solution at room temperature for about 3 s-5 s, to remove any oxide film on the substrate 11.

In step S3, when the pretreatment is finished, the substrate 11 undergoes a composite chemical conversion treatment, to form a composite chemical conversion film 12. The composite chemical conversion treatment includes an inorganic chemical conversion treatment to form an inorganic chemical conversion film 121 on the substrate 11, and an organic chemical conversion treatment to form an organic chemical conversion film 123 on the inorganic chemical conversion film 121.

The inorganic chemical conversion treatment may apply a first solution containing stannate as the main film forming agent. The first solution may be an aqueous solution containing about 150 g/L-250 g/L sodium stannate trihydrate (Na₂SnO₃.3H₂O), and about 80 g/L-150 g/L potassium di-hydrogen phosphate (KH₂PO₄). The inorganic chemical conversion treatment may be carried out by immersing the substrate 11 in the first solution maintained at about 60° C.-80° C. for about 1 hour to 2 hours. In an exemplary embodiment, the first solution is an aqueous solution containing about 200 g/L Na₂SnO₃.3H₂O and about 100 g/L KH₂PO₄. The substrate 11 is immersed in the first solution maintained at about 70° C. for about 2 hours. During the immersion, the first solution may be stirred. By this process, anions in the first solution react with metal atoms on a surface layer of the substrate 11, thus an inorganic chemical conversion film 121 comprising magnesium stannate hydrate (MgSnO₃.H₂O) as a main composition is formed on the substrate 11.

Alternatively, the inorganic chemical conversion treatment may apply a second solution containing cerous salt as the main film forming agent. The second solution may be an aqueous solution containing about 10 g/L-30 g/L cerous nitrate (Ce(NO₃)₃), about 28 g/L-43 g/L hydrogen peroxide (H₂O₂), and about 1 g/L-2 g/L boric acid (H₃BO₃). The inorganic chemical conversion treatment may be carried out by immersing the substrate 11 in the second solution maintained at about 30° C.-60° C. for about 0.2 hour to 2 hours. During the immersion, the second solution may be stirred. In an exemplary embodiment, the second solution is an aqueous solution containing about 15 g/L Ce(NO₃)₃ and about 35 g/L H₂O₂, and about 2 g/L H₃BO₃. The substrate 11 is immersed in the second solution maintained at about 40° C. for about 0.5 hour. By this process, anions in the second solution react with metal atoms on a surface layer of the substrate 11, thus an inorganic chemical conversion film 121 comprising hydroxides of cerium as the main composition is formed on the substrate 11.

The organic chemical conversion treatment may apply a third solution containing oleic acid (also named as cis-9-octadecenoic acid) as the main film forming agent. The third solution is an aqueous solution containing about 10 ml/L-30 ml/L oleic acid, and ketone compounds such as acetone for facilitating the dissolution of the oleic acid. The pH value of the third solution may be between about 2 and 5. The organic chemical conversion treatment may be carried out by immersing the substrate 11 having the inorganic chemical conversion film 121 in the third solution maintained at about 30° C.-50° C. for about 2 min to 4 min. During the immersion, the third solution may be stirred. In an exemplary embodiment, the third solution is an aqueous solution containing about 15 ml/L oleic acid and acetone, with a pH value of about 2.8. The substrate 11 is immersed in the third solution maintained at about 35° C. for about 2.5 min. An organic chemical conversion film 123 is formed on the inorganic chemical conversion film 121.

In step S4, a ceramic coating 13 is formed on the composite chemical conversion film 12 by physical vapor deposition, such as magnetron sputtering or arc ion plating. The ceramic coating 13 may be single layer or multilayer refractory metal compound. The refractory metal compound can be selected from one or more of the group consisting of nitride of titanium, aluminum, chromium, zirconium, or cobalt; carbonitride of titanium, aluminum, chromium, zirconium, or cobalt; and oxynitride of titanium, aluminum, chromium, zirconium, or cobalt. In this exemplary embodiment, the ceramic coating 13 in order includes a first layer 131 adjacent to the organic chemical conversion film 123, and a second layer 132. The first layer 131 is an aluminum-oxygen compound layer. The second layer 132 is an aluminum-oxygen-nitrogen compound layer. An exemplary process for forming the ceramic coating 13 may be performed by the following steps.

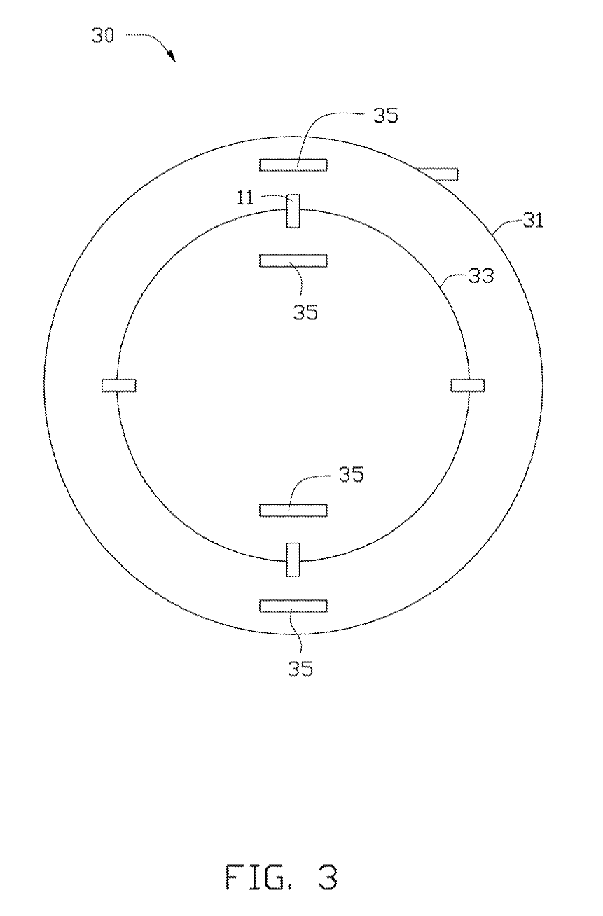

The first layer 131 is directly formed on the composite chemical conversion film 12 by vacuum sputtering. The substrate 11 is hold on a rotating bracket 33 in a chamber 31 of a vacuum sputtering machine 30 as shown in FIG. 3. The chamber 31 is evacuated to maintain an internal pressure of about 6×10⁻³ Pa to 8×10⁻³ Pa and the inside of the chamber 31 is heated to a temperature of about 100° C. to about 150° C. The speed of the rotating bracket 33 is about 0.5 revolutions per minute (rpm) to about 1.0 rpm. Argon and oxygen are simultaneously fed into the chamber 31, with the argon as a sputtering gas, and the oxygen as a reactive gas. The flow rate of argon is about 150 standard-state cubic centimeters per minute (sccm) to about 300 sccm. The flow rate of oxygen is about 50 sccm to 90 sccm. A bias voltage of about −100 volts (V) to about −300 V is applied to the substrate 11. About 8 kW to about 10 kW of electric power is applied to aluminum targets 35 fixed in the chamber 31, depositing the first layer 131 on the composite chemical conversion film 12. Depositing the first layer 131 may take about 30 min to about 60 min. The power may be medium-frequency AC power.

Subsequently, the second layer 132 is directly formed on the first layer 131 also by vacuum sputtering. This step may be carried out in the same vacuum sputtering machine 30. The chamber 31 is evacuated to maintain a pressure of about 6×10⁻³ Pa to 8×10⁻³ Pa, and the inside of the chamber 31 is heated to a temperature of about 100° C. to about 150° C. The speed of the rotating bracket 33 is about 0.5 rpm to about 1.0 rpm. Argon, oxygen, and nitrogen are simultaneously supplied into the chamber 31. The flow rate of argon is about 150 sccm to about 300 sccm. The flow rate of oxygen is about 30 sccm to about 60 sccm, and the flow rate of nitrogen is about 15 sccm to about 40 sccm. A bias voltage of about −100 V to about −300 V is applied to the substrate 11. About 8 kW to about 10 kW of electric power is applied to the aluminum targets 35, depositing the second layer 132 on the first layer 131. Depositing the second layer 132 may take about 30 min to about 120 min.

The composite chemical conversion film 12 has a good chemical stability and high compact density, with a good erosion resistance. In addition, the chemical conversion film 12 provides a smooth surface on the substrate 11, and by such means the ceramic coating 13 formed on chemical conversion film 12 has a substantially even thickness, reducing the susceptibility to pit corrosion. Composed of refractory metal compounds and having a high abrasion resistance, the ceramic coating 13 protects the chemical conversion film 12 from mechanical abrasion.

FIG. 1 shows a cross-section of an exemplary article 10 made of magnesium alloy and processed by the surface treatment process as described above. The article 10 may be a housing for an electronic device, such as a mobile phone. The article 10 includes the substrate 11 made of magnesium alloy, the composite chemical conversion film 12 formed on the substrate 11, and the ceramic coating 13 formed on the composite chemical conversion film 12.

The composite chemical conversion film 12 includes an inorganic chemical conversion film 121 and an organic chemical conversion film 123. The inorganic chemical conversion film 121 is formed by an inorganic chemical conversion treatment using a first solution containing stannate as the main film forming agent, or using a second solution containing cerous salt as the main film forming agent, as described above. The organic chemical conversion film 123 is formed by an organic chemical conversion treatment using a third solution containing oleic acid as the main film agent, as described above.

The ceramic coating 13 may be a single layer or multilayer of refractory metal compound. The refractory metal compound can be selected from one or more of the group consisting of nitride of titanium, aluminum, chromium, zirconium, or cobalt; carbonitride of titanium, aluminum, chromium, zirconium, or cobalt; and oxynitride of titanium, aluminum, chromium, zirconium, or cobalt. In this exemplary embodiment, the ceramic coating 13 orderly includes a first layer 131 adjacent to the composite chemical conversion film 12, and a second layer 132 on the first layer 131. The first layer 131 is an aluminum-oxygen compound layer. The second layer 132 is an aluminum-oxygen-nitrogen compound layer.

A neutral salt spray test was applied to the samples created by the present process. The test conditions included 5% NaCl (similar to salt-fog chloride levels), and the test was an accelerated corrosion test for assessing coating performance Erosion began to be observed after about 72 hours, indicating that the samples resulting from the present process have a good erosion resistance.

It is to be understood, however, that even through numerous characteristics and advantages of the exemplary disclosure have been set forth in the foregoing description, together with details of the system and functions of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A process for surface treating magnesium alloy, the process comprising the following steps of:
providing a substrate made of magnesium alloy;
forming an inorganic chemical conversion film on the substrate by an inorganic chemical conversion treatment;
forming an organic chemical conversion film on the inorganic chemical conversion film by an organic chemical conversion treatment; and
forming a ceramic coating comprising refractory metal compound on the chemical conversion film by physical vapor deposition.

2. The process as claimed in claim 1, wherein the inorganic chemical conversion treatment uses a first solution containing stannate as the main film forming agent.

3. The process as claimed in claim 2, wherein the first solution is an aqueous solution containing about 150 g/L-250 g/L sodium stannate trihydrate, and about 80 g/L-150 g/L potassium di-hydrogen phosphate.

4. The process as claimed in claim 3, wherein the inorganic chemical conversion treatment is carried out by immersing the substrate in the first solution maintained at about 60° C.-80° C. for about 1 hour to 2 hours.

5. The process as claimed in claim 1, wherein the inorganic chemical conversion treatment uses second solution containing cerous salt as the main film forming agent.

6. The process as claimed in claim 5, wherein the second solution is an aqueous solution containing about 10 g/L-30 g/L cerous nitrate, about 28 g/L-43 g/L hydrogen peroxide, and about 1 g/L-2 g/L boric acid.

7. The process as claimed in claim 6, wherein the inorganic chemical conversion treatment is carried out by immersing the substrate in the second solution maintained at about 30° C.-60° C. for about 0.2 hour to 2 hours.

8. The process as claimed in claim 1, wherein the organic chemical conversion treatment uses a third solution containing oleic acid as the main film forming agent.

9. The process as claimed in claim 8, wherein the third solution is an aqueous solution containing about 10 ml/L-30 ml/L oleic acid, and ketone compounds, and having pH value between about 2 and 5.

10. The process as claimed in claim 9, wherein the organic chemical conversion treatment is carried out by immersing the substrate having the inorganic chemical conversion film in the third solution maintained at about 30° C.-50° C. for about 2 min to 4 min.

11. The process as claimed in claimed 1, wherein the refractory metal compound is selected from one or more of the group consisting of nitride of titanium, aluminum, chromium, zirconium, or cobalt; carbonitride of titanium, aluminum, chromium, zirconium, or cobalt; and oxynitride of titanium, aluminum, chromium, zirconium, or cobalt.

12. The process as claimed in claimed 11, wherein the ceramic coating orderly includes a first layer coated on the organic chemical conversion film, and a second layer on the first layer, wherein the first layer is an aluminum-oxygen compound layer, the second layer is an aluminum-oxygen-nitrogen compound layer.

13. The process as claimed in claim 1, further comprising activating the substrate by immersing the substrate in an aqueous solution containing hydrofluoric acid at a concentration of about 1%-3% by weight for about 3 s-5 s, before the inorganic chemical conversion treatment.

14. An article, comprising:
a substrate made of magnesium alloy;
an inorganic chemical conversion film formed on the substrate, the inorganic chemical conversion film being formed by an inorganic chemical conversion treatment;
an organic chemical conversion film formed on the inorganic chemical conversion film, the organic chemical conversion film being formed by an organic chemical conversion treatment; and
a ceramic coating comprising refractory metal compound formed on the chemical conversion film by physical vapor deposition.

15. The article as claimed in claim 14, wherein the inorganic chemical conversion treatment uses a first solution containing stannate as the main film forming agent; the inorganic chemical conversion film comprises magnesium stannate hydrate as a main composition.

16. The article as claimed in claim 14, wherein the inorganic chemical conversion treatment uses a second solution containing cerous salt as the main film forming agent; the inorganic chemical conversion film comprises hydroxides of cerium as the main composition.

17. The article as claimed in claim 14, wherein organic chemical conversion treatment uses a third solution containing oleic acid as the main film forming agent.

18. The article as claimed in claim 14, wherein the refractory metal compound is selected from one or more of the group consisting of nitride of titanium, aluminum, chromium, zirconium, or cobalt; carbonitride of titanium, aluminum, chromium, zirconium, or cobalt; and oxynitride of titanium, aluminum, chromium, zirconium, or cobalt.

19. The article as claimed in claim 18, wherein ceramic coating orderly includes a first layer coated on the organic chemical conversion film and a second layer on the first layer, wherein the first layer is an aluminum-oxygen compound layer, the second layer is an aluminum-oxygen-nitrogen compound layer.
